(19) United States
(12) Patent Application Publication
(10) Pub. No.: US 2026/0162912 A1
(43) Pub. Date: Jun. 11, 2026

(54) MEMS RELAY HAVING INTEGRATED STATE MONITORING AND METHOD FOR OPERATING A MEMS RELAY

(71) Applicant: Robert Bosch GmbH, Stuttgart (DE)

(72) Inventors: Manuel Glueck, St. Johann (DE); Mihel Seitz, Eningen Unter Achalm (DE)

(21) Appl. No.: 19/400,495

(22) Filed: Nov. 25, 2025

(30) Foreign Application Priority Data
Dec. 5, 2024 (DE) 10 2024 136 233.2

(51) Int. Cl. H01H 1/00; G01K 3/00; G01R 31/327

(52) U.S. Cl. CPC H01H 1/0036; G01K 3/005; G01R 31/3278

(57) ABSTRACT

A MEMS relay having integrated state monitoring and a method for operating a MEMS relay.

### FIELD

The present invention relates to a MEMS relay having integrated state monitoring and to a method for operating a MEMS relay.

### BACKGROUND INFORMATION

When a signal is switched on or applied, a decaying oscillation typically occurs before the signal is present without interference. This behavior is denoted as debounce time in signal processing [1]. Debounce time is a critical factor that influences the reliability and accuracy of signal processing. Various approaches to debouncing an electrical signal have been described in the literature.

Sources [3, 4, 5, 6] describe general methods for debouncing electrical signals. These methods comprise both hardware-based and software-based techniques. Hardware-based techniques use electronic circuits, such as RC networks (resistor-capacitor networks) or special debouncing circuits, in order to damp decaying oscillations and generate a clean signal. Software-based techniques, on the other hand, use algorithms implemented in microcontrollers or digital signal processors in order to minimize debounce time and smooth the signal.

A mechanical approach to optimizing debouncing is pursued in [2]. Here, mechanical structures and materials are used to physically damp the oscillations and thereby reduce the debounce time. This method can be particularly useful in applications where electronic debouncing techniques are insufficient or additional mechanical stability is required.

A further aspect of the present invention is the recognition of overloads in a MEMS relay. MEMS relays are sensitive components that must be protected from overvoltage or electrical overload in order to ensure their functionality and service life. In [7], an electronic circuit is described which was specifically designed to protect electronic components, in particular MEMS, from such overloads. This circuit can recognize overvoltages and take appropriate protective measures to prevent damage to the MEMS relays.
[1] Roman Yershov, Volodymyr Voytenko, Volodymyr Bychko, “Software-Based Contact Debouncing Algorithm with Programmable Auto-Repeat Profile Feature” in IEEE International Scientific-Practical Conference Problems of Infocommunications, Science and Technology (PIC S&T), 2019
[2] TW 202040327 A SWITCH DEVICE WITH SWITCH DEBOUNCING AND METHOD OF SWITCH DEBOUNCING THEREOF
[3] US 2020/0328735 A1 METHOD FOR DEBOUNCING AN ELECTRICAL INPUT SIGNAL, AND DEBOUNCING MODULE
[4] US 2009/0303088 A1 MODULAR DEBOUNCING DEVICE
[5] DE 3526416 A1 Circuit arrangement for debouncing a contact
[6] US 2008/062017 A1 DEBOUNCING CIRCUIT
[7] U.S. Pat. No. 6,671,149 B1 CIRCUIT TOPOLOGY FOR PROTECTING VULNERABLE MICRO ELECTRO-MECHANICAL SYSTEM (MEMS) AND ELECTRONIC RELAY DEVICES

### SUMMARY

Providing a status interface for MEMS relays, which gives the user additional information about the state of the relay, offers multiple key advantages over the related art.

Real-time monitoring of the mechanical contact and the provision of information about the full completion of the debouncing phase can ensure that loads are only switched on if the contact is stable and reliably closed. This minimizes the risk of malfunctions and increases operational safety, in particular in safety-critical applications.

The self-diagnosis of the voltage drop across the contact makes it possible to recognize wear or overloads at an early stage. This allows for proactive maintenance and prevents unexpected failures, thus extending the service life of the MEMS relay and the entire system.

Temperature monitoring of the MEMS relay provides indirect information about excessively high rated currents or an excessively high electrical resistance at the contact. This helps to identify overload situations and take appropriate measures before damage occurs.

The ability to implement the status interface as both an analog and a digital interface offers flexibility in integration and adaptation to different system requirements and architectures.

The additional information provided via the status interface makes a detailed diagnosis of the MEMS relay possible. This helps the user to troubleshoot and fix problems, and contributes to optimizing system operation.

Accurate monitoring and diagnosis of the MEMS relay can prevent inefficient operating states. This leads to an overall more efficient use of electrical energy and reduces wear and tear on the components.

The status interface extends the functionality of the MEMS relay by serving not only as a switching element but also as a sensor for various operating parameters. This opens up new application possibilities and improves integration into complex systems.

Thus, by providing a status interface for MEMS relays, the present invention offers significant advantages in terms of reliability, safety, maintenance, diagnostics and system efficiency. These additional functions and information help to optimize the performance and service life of MEMS relays and the associated systems.

Further advantages can be found in the figures and their description herein.

### BRIEF DESCRIPTION OF THE DRAWINGS

FIG. 1 shows a first implementation of a MEMS relay according to an example embodiment of the present invention in schematic representation.

FIG. 2 shows a second implementation of a MEMS relay according to an example embodiment of the present invention in schematic representation.

### DETAILED DESCRIPTION OF EXAMPLE EMBODIMENTS

The same reference signs are used for the same components occurring in the different exemplary embodiments.

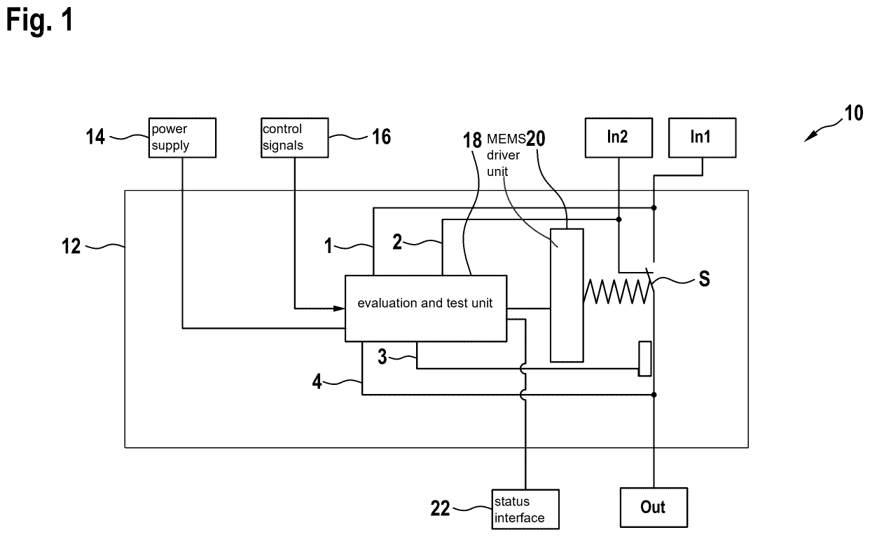

FIG. 1 shows an implementation of a MEMS relay 10 in a housing 12, the relay having at least the following components:
A power supply 14 for the entire system,
Control signals 16 for an evaluation and test unit 18,
The evaluation and test unit 18, which performs the tests and evaluates the results. It receives the power supply 14, the control signals 16 and transmits signals to a MEMS driver unit 20 and a status interface 22.
The MEMS driver unit 20 drives a MEMS switch S.
The MEMS switch S is connected to the MEMS driver unit 20 and the inputs In1 and In2.
In1 & In2: Input signals or voltages for the MEMS switch.
The status interface 22, which outputs the status of the system.
Out: Output signal of the system.
Control lines 1 to 4.

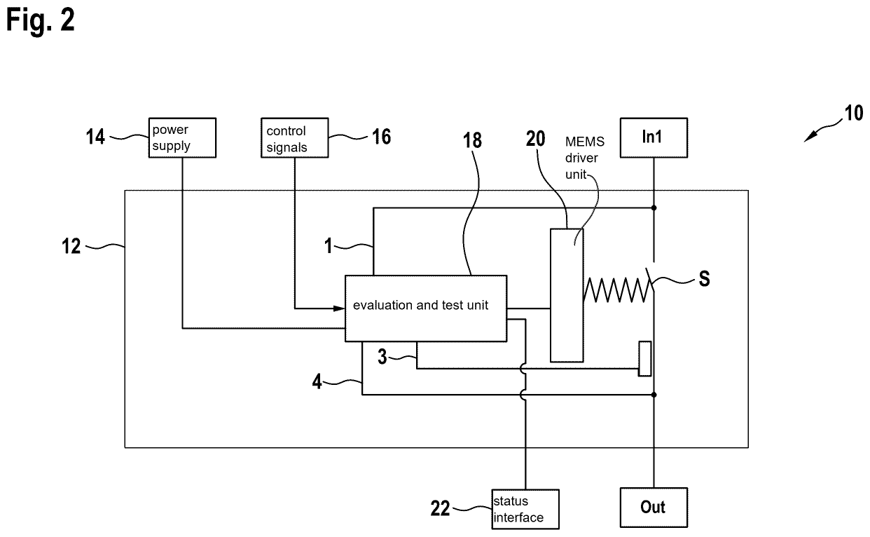

FIG. 2 shows an implementation of a MEMS relay 10 in a housing 12, the relay having at least the following components:
A power supply 14 for the entire system,
Control signals 16 for an evaluation and test unit 18,
The evaluation and test unit 18, which performs the tests and evaluates the results. It receives the power supply 14, the control signals 16 and transmits signals to a MEMS driver unit 20 and a status interface 22.
The MEMS driver unit 20 drives a MEMS switch S.
The MEMS switch S is connected to the MEMS driver unit 20 and the input In1.
In1: Input signal or voltage for the MEMS switch S.
The status interface 22, which outputs the status of the system.
Out: Output signal of the system.
Control Lines 1 to 4.

The MEMS relay offers integrated state monitoring, providing the user with valuable information for diagnostics and system optimization. Feedback on the internal state makes more precise and safer switching possible. For example, the load can only be switched on at the In1/Out pins once the mechanical contact is completely closed, thus minimizing arcing and contact bounce. Furthermore, continuous monitoring of the electrical load on the mechanical contact makes the early recognition of wear or defects possible. On the basis of this information, the user can take preventive measures and thus significantly increase the reliability and service life of the relay, particularly in safety-critical applications.

According to the present invention, various scenarios are provided for.

### Scenario 1: Monitoring the Debounce Time

In this scenario, the evaluation and test unit 18 receives the command to close the MEMS relay 10 at the pin 16. The evaluation and test unit 18 then activates the MEMS driver unit 20 to close the mechanical contact between the In1 and Out pins. The contact can be designed either as a combined make/break contact, as shown in FIG. 1, or as a make contact, as shown in FIG. 2.

In parallel with the switching of the contact, the evaluation and test unit 18 monitors the state of the contact with the aid of the control lines 1 and 4 or 2 and 4. Once the contact is completely closed and the debounce time has elapsed, a flag is set at the status interface 22. This flag can be signaled either via an analog pin or a digital interface.

In contrast to the methods described in sources [3, 4, 5, 6], in this scenario, no subsequent signal processing is performed to suppress debouncing. Instead, the state of the contact is monitored directly, and the user receives immediate feedback as soon as the debouncing phase is complete.

### Scenario 2: Self-Diagnosis of Wear and Electrical Resistance

In this scenario, the MEMS relay 10 from FIG. 1 is in the deactivated state. The In2 and Out pins form an electrically conductive connection. A test current is impressed by the evaluation and test unit 18 with the aid of the control lines 2 and 4. The resulting voltage drop across the MEMS relay 10 represents the electrical resistance of the contact and thus its wear.

This self-test can be performed with the relay in the deactivated state, without the user being aware of it. Alternatively, the voltage drop across the MEMS relay can also be monitored without an additional test current. An increased voltage drop indicates wear of the contact or operation under overload. Limit values derived from existing characterization data provide insights into the operating state. This use case requires that the user has applied an electrical load.

### Scenario 3: Self-Diagnosis of Overload, Wear and Electrical Resistance

In this scenario, the MEMS relay 10 can be implemented either as a combined make/break contact, as shown in FIG. 1, or as a make contact, as shown in FIG. 2. The In1 and Out pins form an electrically conductive connection. The resulting voltage drop across the MEMS relay is ascertained with the aid of the control lines 1 and 4.

The ascertained voltage drop represents the electrical resistance of the contact or, if the electrical resistance is known, the magnitude of the impressed current by the user. If the ascertained voltage drop is too large, the impressed current is outside the specified range. Alternatively, an increased voltage drop indicates damage or wear to the mechanical contact. In both cases, a message can be sent to the user via the status interface. This use case requires that the user has applied an electrical load.

### Scenario 4: Self-Diagnosis of Wear, Electrical Resistance and Overload

In this scenario, the evaluation and test unit 18 monitors the thermal load of the relay using a temperature sensor. Both embodiments, as a combined make/break contact as shown in FIG. 1 or as a make contact as shown in FIG. 2, are possible.

An excessive thermal load indicates either that the mechanical contact of the MEMS relay is no longer in proper condition or that it is being operated outside the specified current range. The status interface can provide the user with feedback about the impermissible operating mode. In the event of repeated thermal overload, wear of the mechanical contact is to be assumed.

1-17. (canceled)

18. A MEMS relay having integrated state monitoring, the relay comprising:
at least one switchable contact; and
an interface configured to output state information, the state information includes at least one of the following pieces of information:
state of the switchable contact, wherein the switchable contact can be open or closed;
electrical load on the switchable contact;
temperature of the MEMS relay.

19. The MEMS relay according to claim 18, wherein the MEMS relay is a make/break contact or a make contact.

20. The MEMS relay according to claim 18, wherein the state information includes the state of the switchable contact and includes a signal indicating when the contact is fully closed and a debounce time has elapsed.

21. The MEMS relay according to claim 18, wherein the state information includes the electrical load on the switchable contact and is ascertained by measuring a voltage drop across the switchable contact.

22. The MEMS relay according to claim 21, wherein the measurement of the voltage drop is carried out in an activated state of the MEMS relay.

23. The MEMS relay according to claim 21, wherein the measurement of the voltage drop in a deactivated state of the MEMS relay is carried out using an impressed test current.

24. The MEMS relay according to claim 18, wherein the state information includes the temperature of the MEMS relay is ascertained by an integrated temperature sensor.

25. The MEMS relay according to claim 18, wherein the interface configured to output the state information is an analog pin or a digital interface.

26. A method for operating a MEMS relay with a switchable contact, a MEMS driver unit, and an evaluation and test unit, wherein the method comprises the following steps:
applying a control signal to the evaluation and test unit to switch the MEMS relay;
actuating the MEMS driver unit by the evaluation and test unit to switch the switchable contact;
monitoring a state of the switchable contact using the evaluation and test unit; and
outputting a status signal when the switchable contact has reached a specified state.

27. The method according to claim 26, wherein the specified state of the switchable contact is a fully closed state after a debounce time has elapsed.

28. The method according to claim 26, wherein the specified state of the switchable contact is a fully open state after a debounce time has elapsed.

29. A method for monitoring wear of a MEMS relay with a switchable contact, a MEMS driver unit, and an evaluation and test unit, wherein the method comprises the following steps:
applying a test current to the switchable contact in the deactivated state of the MEMS relay;
measuring a voltage drop across the switchable contact; and
determining an electrical resistance of the switchable contact based on the measured voltage drop.

30. A method for monitoring an electrical load of a MEMS relay with a switchable contact, a MEMS driver unit, and an evaluation and test unit, wherein the method comprises the following steps:
measuring a voltage drop across the switchable contact in an activated state of the MEMS relay; and
determining the electrical load on the switchable contact based on the measured voltage drop.

31. A method for monitoring a thermal load of a MEMS relay with a temperature sensor, wherein the method comprises the following steps:
measuring a temperature of the MEMS relay using the temperature sensor; and
issuing a warning signal when the measured temperature exceeds a threshold value.

32. The method according to claim 26, wherein the state information is provided either in analog form or digital form.

33. The method according to claim 26, wherein the switchable contact of the MEMS switch is a combined make/break contact or a make contact.

34. The method according to claim 26, wherein the evaluation and test unit is configured to monitor the switchable contact of the MEMS switch and sends a message to a status interface of the MEMS relay in the case of wear of the switchable contact or overload of the switchable contact.
